(19) United States
(12) Patent Application Publication
(10) Pub. No.: US 2014/0183640 A1
(43) Pub. Date: Jul. 3, 2014

(54) GATELESS FINFET

(71) Applicant: INTERNATIONAL BUSINESS MACHINES CORPORATION, Armonk, NY (US)

(72) Inventors: Karl R. Erickson, Rochester, MN (US); Phil C. Paone, Rochester, MN (US); David P. Paulsen, Dodge Center, MN (US); John E. Sheets, II, Zumbrota, MN (US); Gregory J. Uhlmann, Rochester, MN (US); Kelly L. Williams, Rochester, MN (US)

(73) Assignee: INTERNATIONAL BUSINESS MACHINES CORPORATION, Armonk, NY (US)

(21) Appl. No.: 13/733,270

(22) Filed: Jan. 3, 2013

(51) Int. Cl. H01L 29/78; H01L 29/66

(52) U.S. Cl. CPC H01L 29/7855; H01L 29/66795
USPC 257/365; 438/283

(57) ABSTRACT

A finFET includes a semiconductor fin formed on a base. The fin further includes a body area between a first vertical surface and a second vertical surface. The finFET includes a first contact adjacent to the first vertical surface of the body area. The first vertical surface is spaced away from the first contact by a first dielectric thickness. Also included is a second contact adjacent to the second vertical surface of the body area. The second vertical surface is spaced away from the second contact by a second dielectric thickness. The first dielectric thickness and second dielectric thickness are configured to allow the first contact and second contact to modulate the body area of the fin.

### FIELD

This invention relates generally to semiconductor devices, and more specifically to finFETs.

### BACKGROUND

A semiconductor device is a component of most electronic systems. Field effect transistors (FETs) have been the dominant semiconductor technology used to make application specific integrated circuit (ASIC) devices, microprocessor devices, static random access memory (SRAM) devices, and the like, for many years. In particular, complementary metal oxide semiconductor (CMOS) technology has dominated the semiconductor process industry.

Technology advances have scaled FETs on semiconductor devices to small dimensions allowing power per logic gate to be dramatically reduced, and further allowing a very large number of FETs to be fabricated on a single semiconductor device. However, traditional FETs are reaching their physical limitations as their size decreases. To address this problem finFETs are a recent development. FinFETs use three-dimensional techniques to pack a large number of FETs in a very small area.

### SUMMARY

In an embodiment, a fin field effect transistor (finFET) is described. The finFET includes a semiconductor fin formed on a base. The fin further includes a body area between a first vertical surface and a second vertical surface. The finFET includes a first contact adjacent to the first vertical surface of the body area. The first vertical surface is spaced away from the first contact by a first dielectric thickness. Also included is a second contact adjacent to the second vertical surface of the body area. The second vertical surface is spaced away from the second contact by a second dielectric thickness. The first dielectric thickness and second dielectric thickness are configured to allow the first contact and second contact to modulate the body area of the fin.

In another embodiment, a method of forming a fin field effect transistor (finFET) is described. The finFET includes fabricating a semiconductor fin formed on a base. The fin further includes a body area having substantially the same width between a first vertical surface and a second vertical surface. The method includes forming a first contact adjacent to the first vertical surface, wherein there is a first dielectric thickness between the first vertical surface and the first contact. The method further includes forming a second contact adjacent to the second vertical surface, wherein there is a second dielectric thickness between the second vertical surface and the second contact. The first dielectric thickness and the second dielectric thickness are configured to allow the first and second contacts to modulate the body area of the fin.

### BRIEF DESCRIPTION OF THE DRAWINGS

Embodiments will be better understood from the following detailed description with reference to the drawings, in which:

FIGS. 1-7 illustrate sequential isometric views of a process for creating an exemplary finFET structure according to an embodiment.

FIG. 1 illustrates an isometric drawing of a finFET structure fabricated by known techniques according to an embodiment.

FIG. 2 illustrates an isometric drawing of a semiconductor device including a finFET structure after a dielectric is added according to an embodiment.

FIG. 3 illustrates an isometric drawing of the semiconductor device with an additional thick dielectric according to an embodiment.

FIG. 4A illustrates an isometric drawing of the semiconductor device after selective etching of the thick dielectric according to an embodiment

FIG. 4B illustrates a cross-sectional view of the semiconductor device of FIG. 4A along the plane A-A′ according to an embodiment.

FIG. 4C illustrates a cross-sectional view of an alternative embodiment of the semiconductor device of FIG. 4A along the plane A-A′ according to an embodiment.

FIG. 5A illustrates an isometric drawing of the semiconductor device after the thick dielectric is removed and a source and a drain of the finFET structure are defined according to an embodiment.

FIG. 5B illustrates a cross-sectional view of the semiconductor device of FIG. 5A along the plane B-B′ according to an embodiment.

FIG. 6 illustrates an isometric drawing of the semiconductor device after additional dielectric and thick dielectric are added according to an embodiment.

FIG. 7 illustrates an isometric drawing of the semiconductor device after a planarization according to an embodiment.

FIG. 8 illustrates an isometric drawing of the semiconductor device of an alternative process according to an embodiment.

FIG. 9 illustrates an isometric drawing of the semiconductor device after an additional process step of the alternative process according to an embodiment.

FIG. 10 illustrates a flowchart of a method of manufacturing a gateless finFET semiconductor device according to an embodiment.

### DETAILED DESCRIPTION

Features illustrated in the drawings are not necessarily drawn to scale. Descriptions of well-known components and processing techniques are omitted so as to not unnecessarily obscure the disclosed embodiments. The descriptions of embodiments are provided by way of example only, and are not intended to limit the scope of this invention as claimed. The same numbers may be used in the Figures and the Detailed Description to refer to the same devices, parts, components, steps, operations, and the like.

The production of traditional field effect transistors (FETs) is currently running into physical barriers when creating small, fast semiconductor devices. Gate oxides have become thin enough that current leakage occurs through the gate oxides. Further scaling of gate oxide thickness will bring an exponential increase in current leakage. Power dissipated by current leakage has become a significant portion of total device power, and an exponential increase in current leakage may result in unacceptable power dissipation for many types of devices.

Silicon on Insulator (SOI) processes that have been introduced have reduced FET source and drain capacitances, resulting in an improved power/performance ratio for CMOS devices fabricated in an SOI process. However, conventional SOI processes are also reaching fundamental limits, resulting in undesirable effects such as the current leakage effects mentioned above. Therefore, innovative ways to make CMOS devices are being created such as finFETs.

A finFET is a FET device that utilizes three-dimensional techniques to pack a large number of FETs in a given area of a semiconductor device, which addresses the scaling problems described above. FinFETs have at least one narrow semiconductor fin that may be as narrow as 10 nm in width. This fin may be gated by electrodes at one or more locations along the length of the fin. Each end of the fin may either make up the source or the drain of the FET. Typically, silicon makes up the semiconductor material of the fin, but other semiconductor materials may be used. Also, gate electrodes may be made of conductors such as polysilicon. A gate oxide layer may insulate the gate electrode from the fin semiconductor material. The gate oxide layer may be much thinner than the gate electrode. The gate oxide may be a dielectric such as SiO₂, HfO₂, or Si₃N₄. In regions where the substrate material is doped, for example P− (for an N− channel FET, an NFET), the source and the drain areas are also doped to become N+ regions, with the P− region under gate electrode serving as a body of the finFET. Gate electrode contacts (contacts), made of a conducting material, may be coupled to each gate electrode to provide signals to the gate electrodes to effectively “turn on” or “turn off” each gate electrode.

FinFETs have significant advantages. Being “three dimensional” FETs, the gate electrode may induce conducting channels on three sides of the fin, increasing current flow through a conducting FET, and making it less necessary that the gate oxide layer be as thin as the gate oxide of a conventional planar FET.

Several drawbacks may exist in the current state of the art of finFETs. One such drawback may be the large parasitic capacitance between the drain, the source, and other nearby circuits. Also, the patterning of the gate electrode over the extreme fin topology is of great complexity and concern. Particularly, dimensional control and uniformity of the gate electrode up the vertical surface of the fin versus the gate electrode length across the top of the fin are difficult to equalize. Furthermore, the large capacitance between gate electrode contacts and the transistor channel may be problematic in certain situations as well as the large landing area required by the gate electrode contact. The landing area of the contact may be far away from the fin causing the entire finFET structure to use extra area on the semiconductor chip. Eliminating the gate electrodes and using gate electrode contacts themselves as the gate signaling structure may allow for increased power performance. This may also increase density of FETs due to the elimination of the space required for gate contacts and higher current density per unit of substrate area due to the high aspect ratio fin.

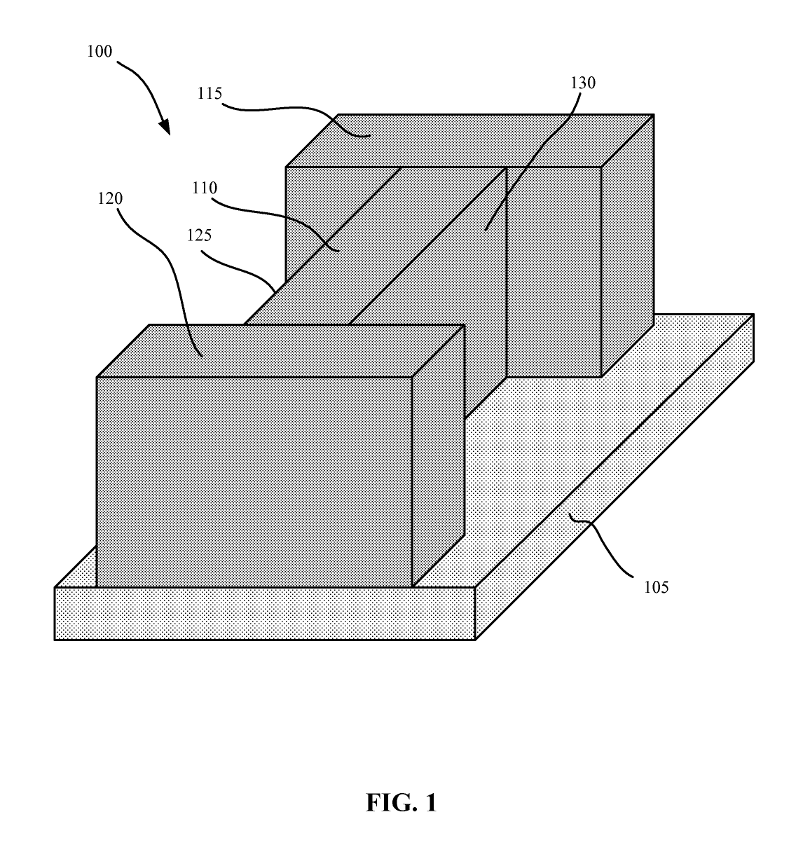

FIGS. 1-7 show sequential views of exemplary manufacturing stages of an exemplary FinFET structure according to an embodiment. Figures with the same numeric label correspond to the same stage of manufacturing. The figures are not drawn to scale. The dimensions may vary in some embodiments. Also, the shapes of the figures may depict ideal shapes. Variations in actual manufacturing may result in structures deviating from the depicted figures.

Referring to FIG. 1, according to an embodiment, a finFET structure may be fabricated according to known techniques. In FIG. 1, the shown finFET structure is referred to as a semiconductor device 100. However, the semiconductor device 100 generally refers to the finFET structure in the various manufacturing stages described herein. The semiconductor device 100 may include an insulated base 105, a fin 110, a source 115, and a drain 120. The source 115 and the drain 120 may be interchangeable.

In one embodiment, the insulated base 105 may be buried oxide on a semiconductor substrate with the semiconductor fin 110 on top of the buried oxide (SOI finFET). The buried oxide may be SiO₂ or other insulator. The semiconductor substrate may be single crystal silicon. However, the semiconductor substrate may be other appropriate semiconducting materials, including, but not limited to, SiC, Ge alloys, GaP, InAs, InP, SiGe, GaAs, other III/V or II-VI compound semiconductors, or other crystalline structures. In other embodiments, the insulated base 105 may be part of a bulk finFET where the base 105 includes a semiconductor substrate that the fin 110 rises from and an oxide layer may be deposited on top of the substrate. The oxide layer may be etched away to expose the fin.

The fin 110 may be a silicon based structure that rises from substrate of the base 105 and has a doping suitable for a body area of a FET (e.g., P− doping, in the case of an NFET). The fin may have a dopant concentration typically in the range from about 5.0*10¹⁴/cm³ to about 5.0*10¹⁷/cm³. Besides silicon, the fin 110 may be made of other appropriate semiconducting materials, including, but not limited to, SiC, Ge alloys, GaP, InAs, InP, SiGe, GaAs, other III/V or II-VI compound semiconductors or other crystalline structures. The fin 110 may have a first vertical surface 125 and a second vertical surface 130, which in between resides the body area of the fin 110. The height of the fin 110 may be in the range from about 50 nm to 1000 nm, although larger or smaller heights are also contemplated. The width of the semiconductor fin 110 preferably is from 10 nm to 500 nm, although larger or smaller widths are also contemplated. The ratio between the height and width of the fin 110 may be of a ratio of 2:1, although other ratios such as 1:1 and 3:1 are contemplated. Also, the illustration of the fin 110 throughout the figures represents an ideal shape of the fin 110. The fin 110 may be substantially rectangular in shape. However, variations in manufacturing may make the corners of the fin 110 rounded, and the vertical surfaces of the fin 110 may not be parallel with one another or perpendicular to the base 105. The source 115 and drain 120 regions may be appropriately doped in subsequent steps to distinguish them from the finFET body area.

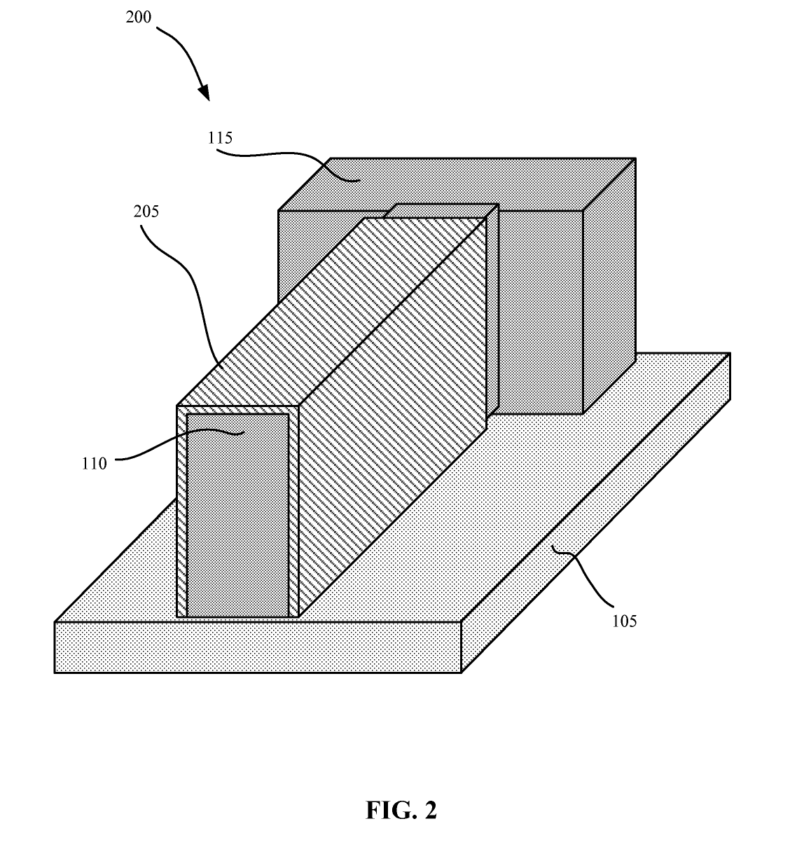

Referring to FIG. 2, according to an embodiment, a dielectric 205 is deposited over the fin 110. The semiconductor device 100 of FIG. 1 may be now referred to as semiconductor device 200. Also in FIG. 2, the drain 120 is omitted from the isometric drawing for clarity. The dielectric 205 may be a high-κ dielectric (where κ is the dielectric constant) such as HfO₂; however, other dielectrics such as Si₃N₄ or SiO₂ may be used.

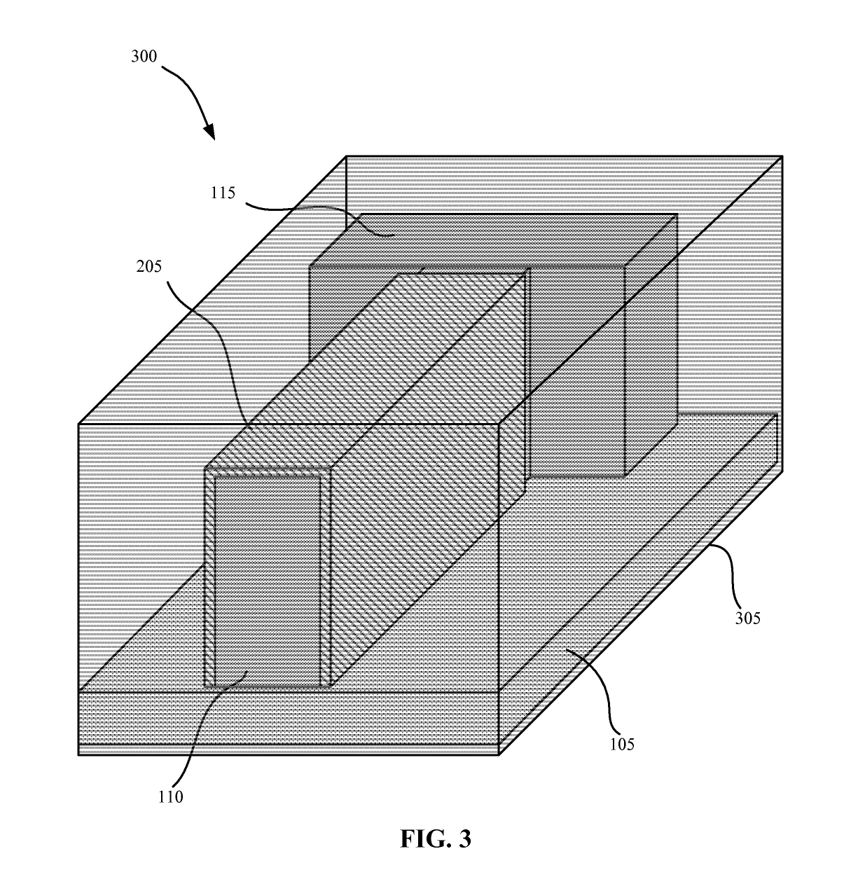

Referring to FIG. 3, according to an embodiment, a thick dielectric 305 is deposited over the semiconductor device 200 of FIG. 2, forming semiconductor device 300. The thick dielectric 305 may be SiO₂; however, any dielectric may be used, such as HfO₂or Si₃N₄. The thick dielectric 305 may be applied over the entire surface of the semiconductor device 300, ideally having an equal or higher vertical profile than the fin 110. The thick dielectric 305 may be planarized by known techniques. In FIG. 3 and herein, the thick dielectric 305 is illustrated as being transparent to show other structures within the semiconductor device 300. However, it should be understood that this is for purposes of illustration only and the thick dielectric 305 may not be transparent.

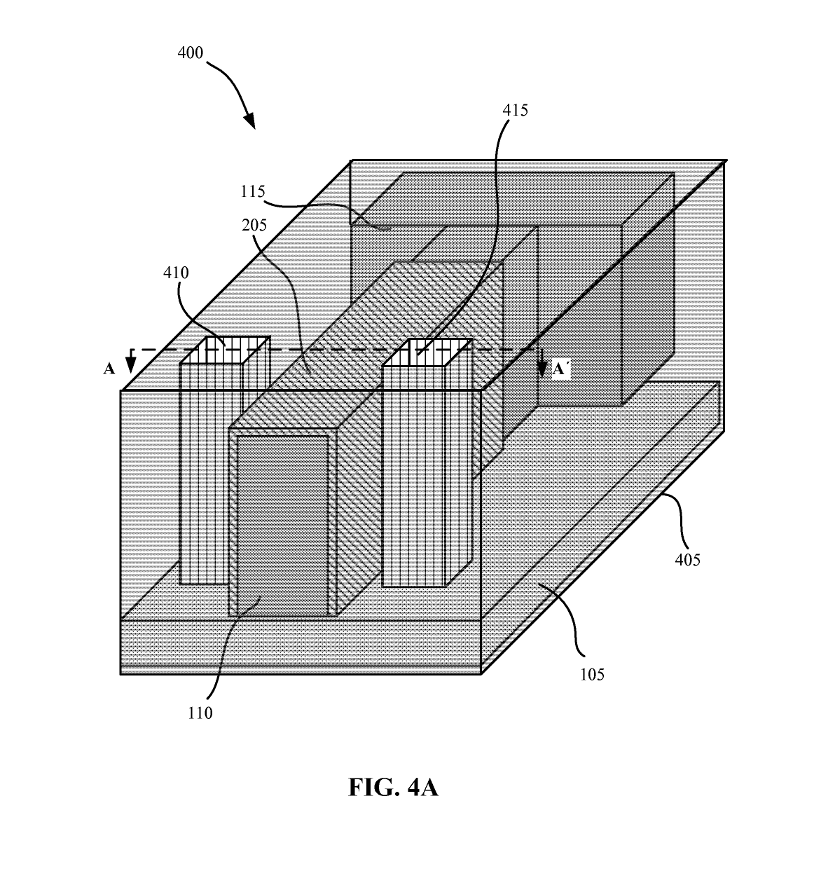

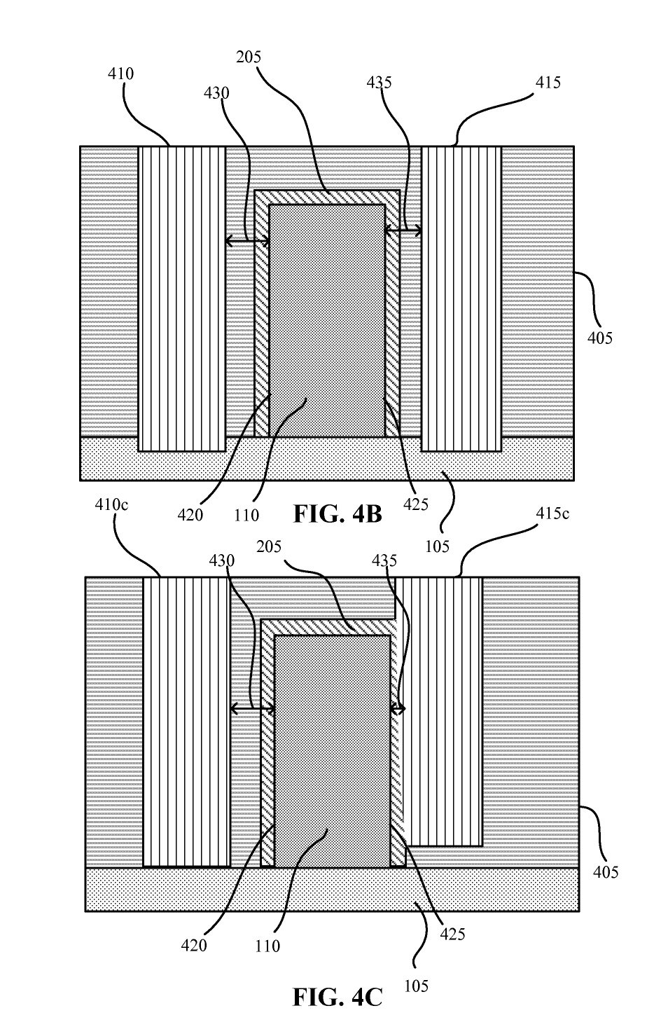

Referring to FIG. 4A, according to an embodiment, contact openings may be selectively etched in the semiconductor device 300 of FIG. 3, forming the semiconductor device 400. A first contact opening 410 and a second contact opening 415 may be selectively etched by known techniques in the thick dielectric 305 of FIG. 3 forming thick dielectric 405. The first and second contact openings 410, 415 may be etched at locations adjacent to the first and second vertical surfaces, as shown in FIG. 4A.

Referring to FIG. 4B, a vertical cross-sectional view of the semiconductor device 400 along plane A-A′ is illustrated. The contact openings 410, 415 may extend to a level below where the fin 110 extends into the base 105. The vertical surface of the first etched contact opening 405, adjacent to the fin 110, may be a first distance 430 from a first vertical surface 420 of the fin 110. A vertical surface of the etched second contact opening 405, adjacent to the fin 110, may be a second distance 435 from a second vertical surface 425 of fin 110. The area defined by the first distance 430 and second distance 435 may be made up of the dielectric 205 and the thick dielectric 405. The first distance 430 may also be referred to as first dielectric thickness. The second distance 435 may also be referred to as second dielectric thickness.

FIG. 4C illustrates an alternative embodiment of the semiconductor device 400 along the A-A′ plane. In this embodiment, the contact openings 410, 415 may extend to the base of the fin 110 as the first contact opening 410c does, or the contact openings 410, 415 may extend to a depth in the thick dielectric 405 that does not reach the depth of the base of the fin 110 as illustrated by the second contact opening 415c. The second contact opening 415c may still extend to a depth where the vertical surface of the contact opening 415c is adjacent to a portion of the second vertical surface 425 of the fin 110. Also, when etching out the thick dielectric 405, by etching close to the fin 110 and dielectric 205, the etching of thick dielectric 405 may remove part of dielectric 205, as shown in FIG. 4C on the right side of the fin 110. If the dielectric 205 is HfO₂ and the thick dielectric 405 is SiO₂, then the SiO₂ may etch away at a faster rate than the HfO₂ (about a 20:1 etch ratio). In another embodiment, Si₃N₄ may be layered on top of the dielectric 205 of HfO₂ to provide even greater etchant selectivity (about a 100:1 etch ratio). This may further encourage the contact openings 410c and 415c to overlap the dielectric 205. Adequate dielectric thickness between the vertical surface of the second contact opening 415c and the second vertical surface 425 of the fin 110 may be needed so that adequate amounts of dielectric 205 separate the contact (to fill in the contact openings 410c, 415c) from the fin 110 so as to not create a short circuit with the fin 110. Also, if there is inadequate dielectric between the contact and the fin 110, current leakage may occur. If the selective etch removes the dielectric 205 and exposes the fin 110, then the contact openings 410c, 415c may be lined with a high-κ dielectric, such as HfO₂ or Si₃N₄, before the contact openings are filled with a conductive material.

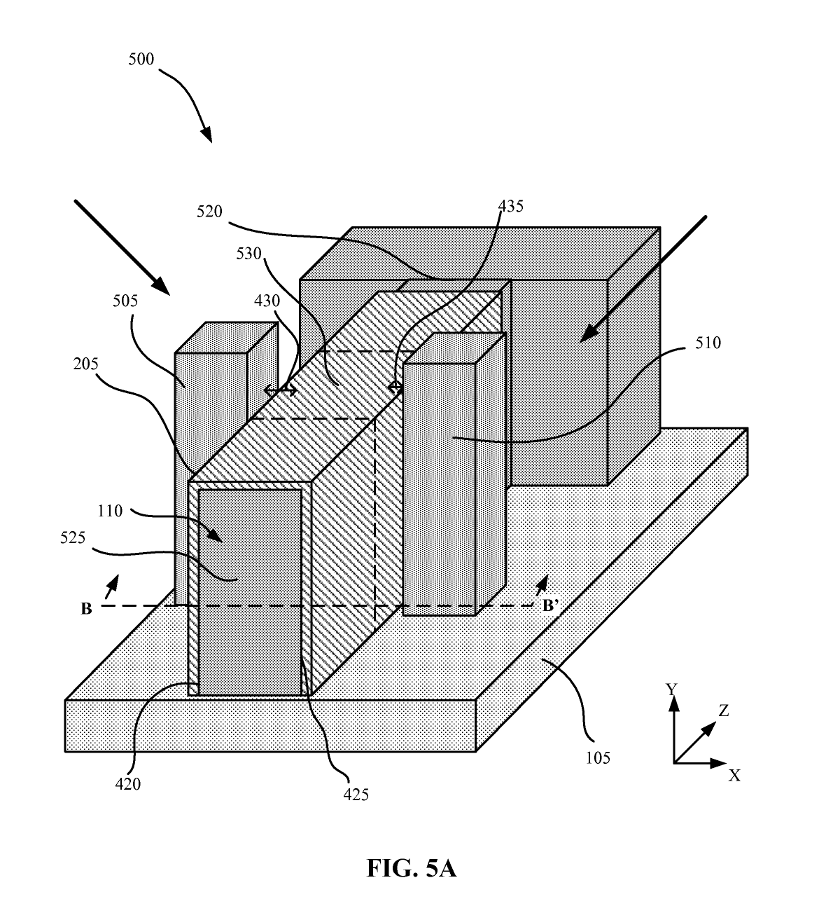

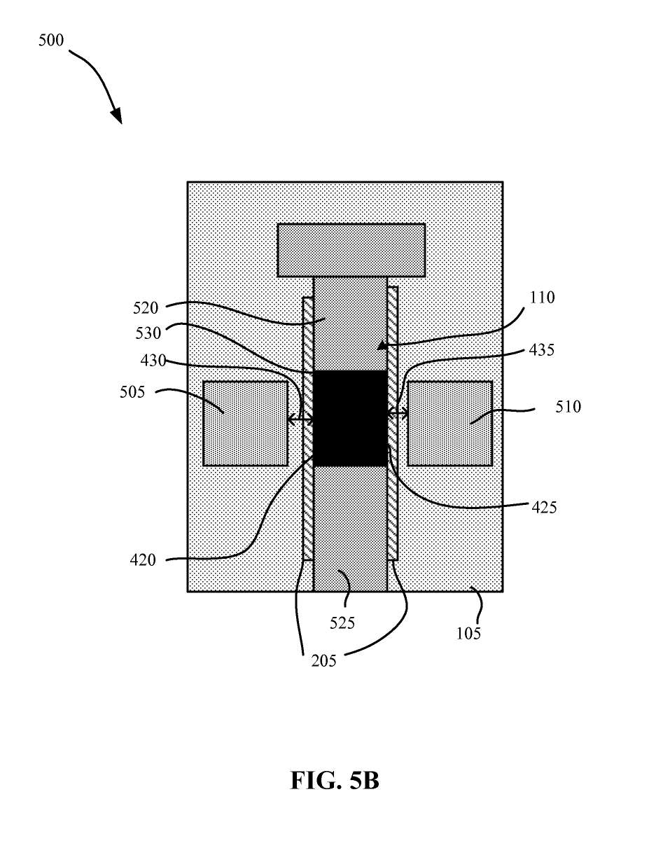

Determining the first distance 430 between the first vertical surface 420 and the first contact 505 (FIG. 5) may be application specific. Determining the second distance 435 between the second vertical surface 425 of the fin 110 and the second contact 510 (FIG. 5) may be application specific. Also, determining which dielectric to use between the contacts and the body area of the fin 110 may be application specific. The drive current of the finFET may be proportional to the gate capacitance. The gate capacitance may be modeled by the equation:

C=κε₀A/t

The relative dielectric constant of the dielectric material is κ. SiO₂has a dielectric constant of 3.9 while HfO₂has a dielectric constant of 25. The permittivity of free space is εₐ The height of the contact times the width of side of the contact facing the body of the fin 110 is the area, A. The thickness of the dielectric is t. Having a higher-κ dielectric may allow for a thicker layer of dielectric 205 to get a higher or similar gate capacitance than a low-κ dielectric. If the dielectric is too thin, current leakage from the contacts to the body of the fin 110 may occur. The area of the face of the contacts may also be adjusted accordingly for application specifics.

Referring to FIG. 5A, according to an embodiment, the contact openings of the semiconductor device 400 of FIG. 4 are filled. The first contact opening 410 and second opening 415 may be filled with a conductive material such as, but not limited to, W, Ti, Ta, Cu, or Al. The conductive material may fill the first and second contact openings 410, 415 to the level of the top of the thick dielectric 405. In other embodiments, the conductive material may fill the contact openings 410, 415 to an application specific height. The thick dielectric 405 may be removed by a blanket etch according to known techniques. Removal of the thick dielectric 405 leaves the filled contact openings 410, 415 forming a first contact 505 and a second contact 510. The dielectric 205 may not etch away if it is a high-κ dielectric, such as HfO₂, when performing a blanket etch, since high-κ dielectrics etch at a much slower rate than low-κ dielectrics such as SiO₂. Semiconductor device 400 of FIG. 4 is now referred to as semiconductor device 500. The first and second contacts 505, 510 may extend well above the top of the fin 110 active region and may extend below the bottom of the fin 110. In another embodiment, the first and second contacts 505, 510 may be lined with a semiconductor material, initially, to make the work function consistent across the gate and body channel.

The first contact 505 and second contact 510 may be used to define the source 115 and drain 120 regions of the semiconductor device 100 of FIG. 1. Two highly angled dopant implantations may be used to define a source 520 and a drain 525 in the semiconductor material of fin 110 of semiconductor device 500. Boron may be a dopant used for PFETs while phosphorus, arsenic, or antimony may be used as a dopant for NFETs. The dopant may be implanted at an angle on the order of 45 degrees to the first and second vertical sides 420, 425 and the x-z plane with the semiconductor device 500 oriented normal to the dopant implantation beam, thereby allowing the first contact 510 and second contact 515 to define a self-aligned body area 530 between the implanted source 520 and drain 525. The source 520 and drain 525 may have a dopant concentration from about 1.0*10¹⁹/cm³ to about 5.0*10²¹/cm³, and preferably from about 1.0*10²⁰/cm³ to about 1.0*10²¹/cm³. The body area 530 may retain its doping, which is the complementary doping of the source 520 and drain 525 (e.g., P− doping, in the case of an NFET). The implanted source 520 and drain 525 are activated via Rapid Thermal Anneal or similar activation techniques.

Referring to FIG. 5B, according to an embodiment, a horizontal cross-sectional view along the plane B-B′ of the semiconductor device 500 after the doping of the source and drain with the angled dopant implantation is illustrated. The fin 110 may now have the source 520, the drain 525, and the body area 530. The first contact 505 and the second contact 510 may be used to keep the body area 530 with its original dopant, P− dopant in the case of an NFET, while the source 520 and the drain 525 may be implanted with an N+ dopant.

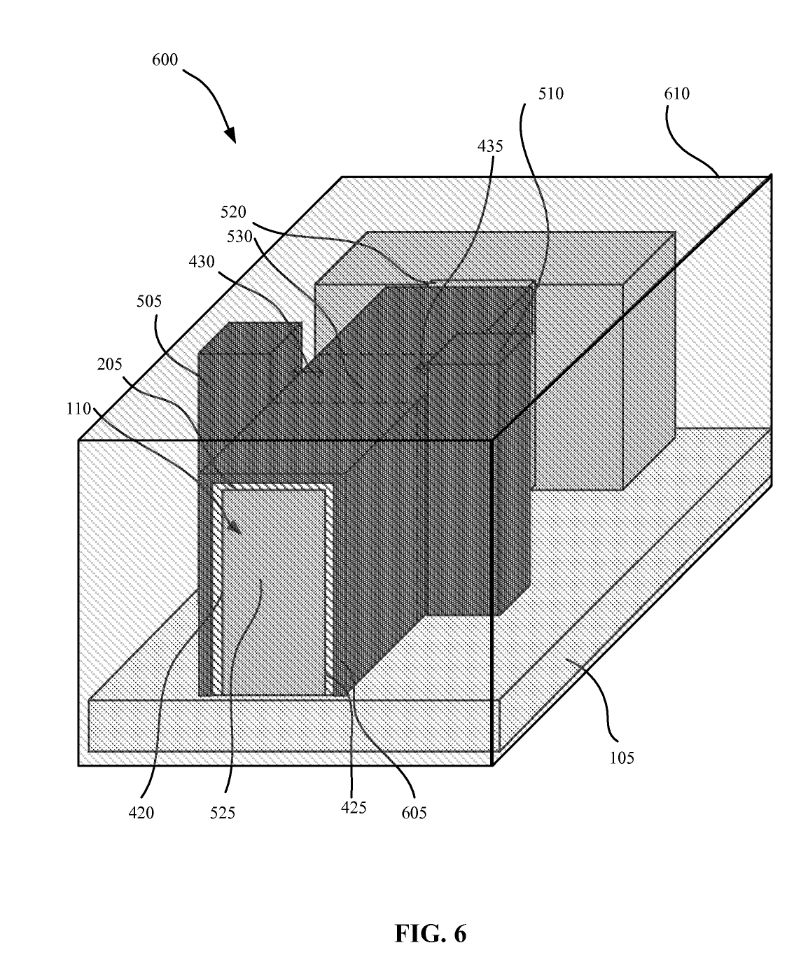

Referring now to FIG. 6, according to an embodiment, a film 605 with a high dielectric constant may be deposited on the semiconductor device 500 of FIG. 5. The film 605 may cover the components of the semiconductor device 500 of FIG. 5 forming semiconductor device 600. The film may fill the areas defined by the first distance 430 and second distance 435, which may not be completely filled with dielectric 205. The film 605 may be made of a material that has a high dielectric constant such as HfO₂ or Si₃N₄. The high dielectric constant film 605 may enhance the capacitance between the contacts 505, 510 and the body area 530. Also, the high dielectric constant film 605 may limit current leakage from the contacts 505, 510 to the body area 530, which may occur if a dielectric with a lower dielectric constant was used such as SiO₂ . A thick dielectric 610 may be deposited over the semiconductor device 600 to insulate the components.

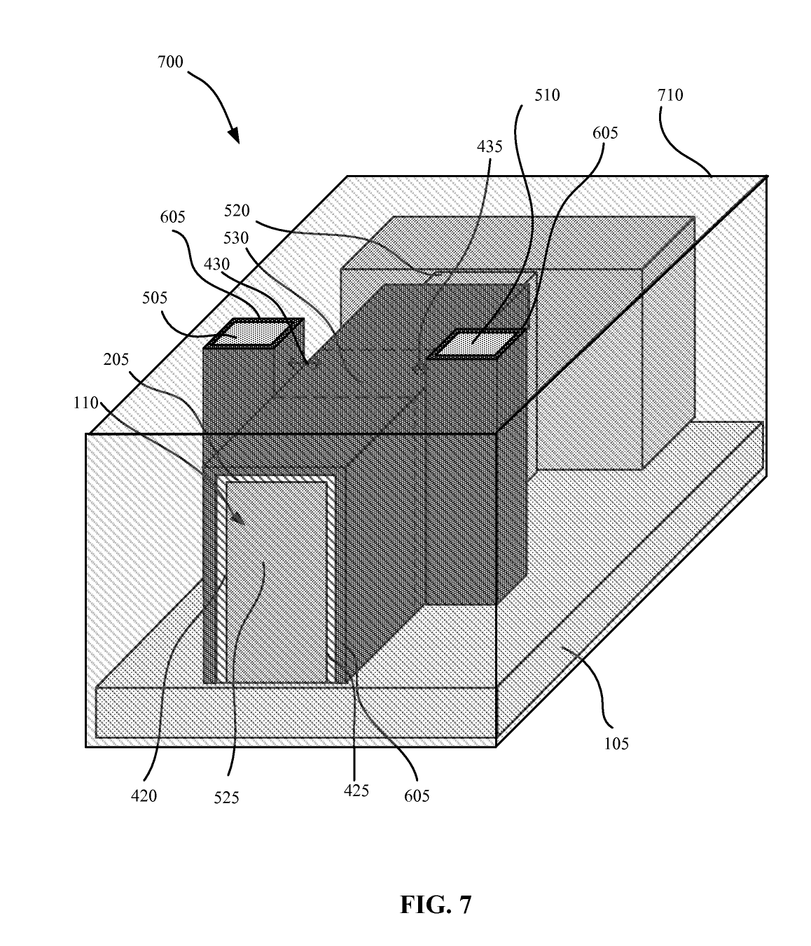

Referring now to FIG. 7, according to an embodiment, the thick dielectric 610 may be polished on the semiconductor device 600. The thick dielectric 610 may be polished to expose the first contact 505 and second contact 510, forming thick dielectric 710. Semiconductor device 600 of FIG. 6 may now be referred as semiconductor device 700. The dielectric polish may expose the tops of the first and second contacts 505, 510 so that they may be coupled with a voltage supply.

In an alternative embodiment, the first and second contacts 505, 510 may be polished down to a point near the top of the fin 110. The semiconductor material at the top of the fin 110 may be modulated by the subsequent top fin contact made of conductive material connected to the contacts 505, 510 across the top of the fin 110. The top fin contact may also be electrically isolated from the first contact 505 and the second contact 510 in an alternative embodiment. A top fin dielectric layer may separate the top of the fin 110 with the top fin contact. The top fin dielectric layer may span a vertical distance between the top of the fin 110 to the top fin contact. Vertical distance may be referred to as vertical dielectric thickness herein. The additional top fin contact across the top of the fin 110 may increase modulation of the semiconductor body area 530 of the fin 110 in situations where the height to width ratio of the fin 110 is close to 1:1. As the height to width ratio gets larger, such as 2:1 or 3:1, the usefulness of the additional conductor across the top of the fin 110 in modulating the semiconductor channel decreases due to less area at the top of the fin 110.

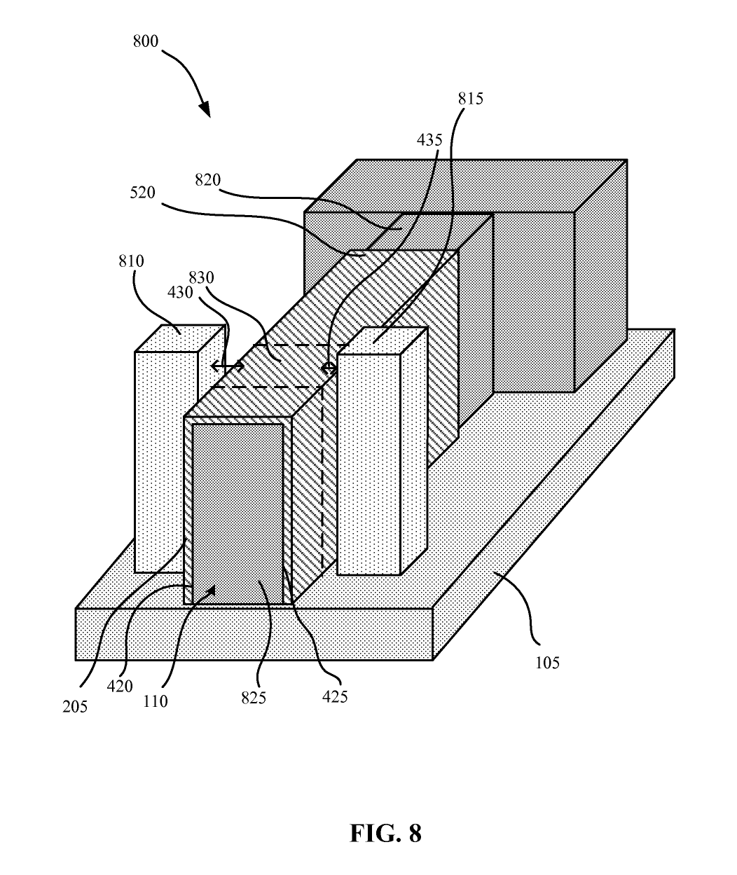

Referring now to FIG. 8, according to an alternative embodiment, the fin 110 may have its source and drain defined prior to the contact metallization in FIG. 5. The contact openings 410 and 415 of FIG. 4 may be filled with a second dielectric film having a different dielectric constant than the thick dielectric 405, such as a nitride, forming a first spire 810 and a second spire 815. The thick dielectric 405 may be etched away from semiconductor device 400 of FIG. 4, referred to now as semiconductor device 800. The selective etch may leave most of the first and second spires 810, 815. The first spire 810 and second spire 815 may be used during the angled dopant implantation as described above in FIG. 5 to define the source 820, drain 825, and body area 830 of the fin 110.

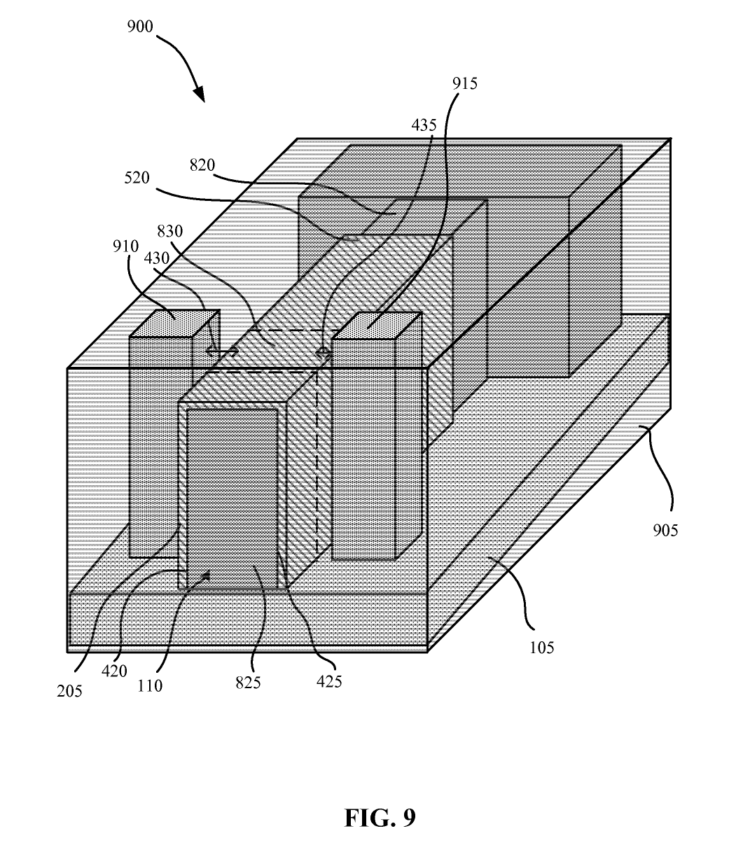

Referring now to FIG. 9, a thick dielectric layer 905 may be deposited over the semiconductor device 800 of FIG. 8, forming semiconductor device 900. The first spire 810 and second spire 815 may be etched and subsequently filled with a conductive material forming the first contact 910 and the second contact 915.

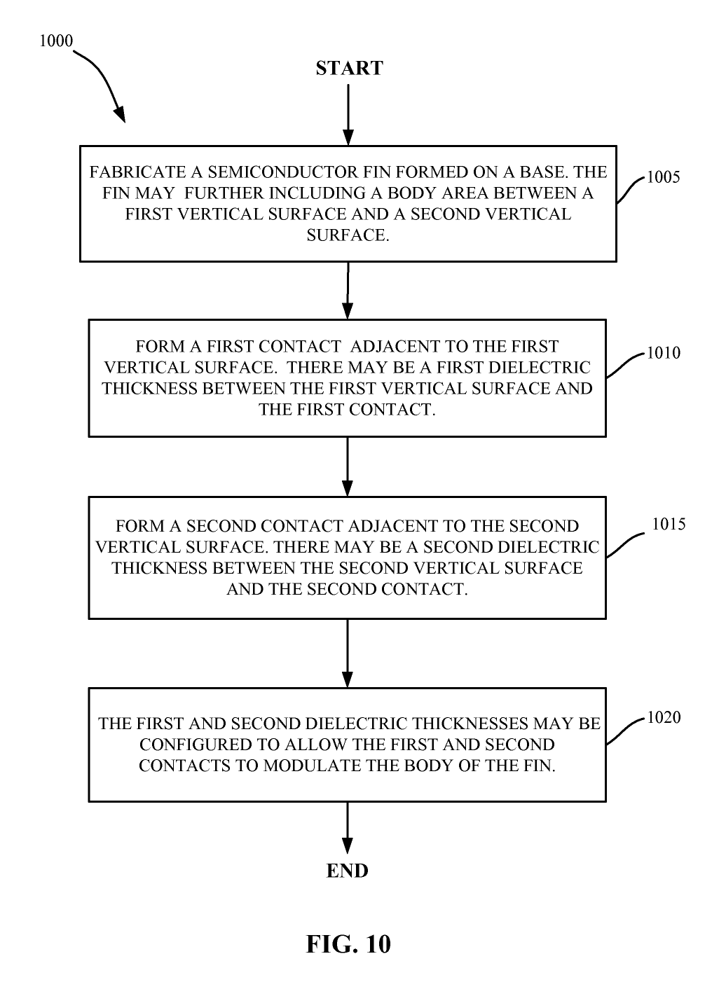

Referring to FIG. 10, a method 1000 is described for forming a gateless semiconductor device according to an embodiment. In operation 1005, a semiconductor fin, e.g., fin 110 (FIG. 1) may be fabricated on a base with a semiconductor material such e.g., silicon. However, other semiconductor materials are contemplated. The fin may include a body area between a first vertical surface and a second vertical surface. In operation 1010, a first contact may be formed adjacent to the first vertical surface. There may be a first dielectric thickness between the first vertical surface and the first contact. In operation 1015, a second contact may be formed adjacent to a second vertical surface of the body of the fin. There may be a second dielectric thickness between the second vertical surface and the second contact. In operation 1020, the first and second dielectric thickness may be configured to allow the first and second contacts to modulate the body of the fin. The first and second contacts may be made of a conducting material such as Cu. Operations 1010, 1015, and 1020 need not to be completed in the order they are given. Operations 1010 and 1015 may be performed simultaneously and operation 1020 may occur before operations 1010 and 1015.

While the invention has been described with reference to specific embodiments thereof, those skilled in the art will be able to make various modifications to the described embodiments without departing from the true spirit and scope of the embodiments. The terms and descriptions used herein are set forth by way of illustration only and are not meant as limitations. Those skilled in the art will recognize that these and other variations are possible within the spirit and scope of the embodiments as defined in the following claims and their equivalents.

1. A fin field effect transistor (finFET) comprising:
a semiconductor fin formed on a base, the fin further including a body area between a first vertical surface and a second vertical surface;
a first contact adjacent to the first vertical surface of the body area, and the first contact having a height greater than a combined height of the body area and a gate dielectric, wherein the first vertical surface is spaced away from the first contact by a first dielectric thickness; and
a second contact adjacent to the second vertical surface of the body area, and the second contact having a height greater than the combined height of the body area and the gate dielectric and the second contact electrically isolated from the from the first contact, wherein the second vertical surface is spaced away from the second contact by a second dielectric thickness, wherein the first dielectric thickness and second dielectric thickness are configured to allow the first contact and second contact to modulate the body area of the fin.

2. The finFET of claim 1, further comprising:
a source on a first side of the body area and a drain on a second side of the body area.

3. The finFET of claim 2, wherein the source, drain, and body area of the fin are defined by an angled dopant implantation, angled with respect to the first and second vertical surfaces and masked by the first and second contacts.

4. The finFET of claim 3, wherein the angled dopant implantation is on the order of 45 degrees with respect to the first and second vertical surfaces.

5. The finFET of claim 4, wherein the first and second contacts used when defining the source, drain, and body area are a respective first spire and a second spire made of a dielectric.

6. The finFET of claim 1, further comprising:
a top fin dielectric layer deposited on a top fin area of the body area having a vertical dielectric thickness; and
a top fin contact on the top fin dielectric layer, wherein the vertical dielectric thickness separating the top fin area and the top fin contact is configured to allow the top fin contact to modulate the body area of the fin.

7. The finFET of claim 6, wherein the top fin contact is coupled to the first contact and the second contact.

8. The finFET of claim 6, wherein the top fin contact is electrically insulated from the first contact and the second contact.

9. The finFET of claim 6, wherein the first contact, the second contact, and the top fin contact are made of a conductive material.

10. The finFET of claim 6, wherein the first dielectric thickness, the second dielectric thickness and the vertical dielectric thickness are made of one or more layers of different dielectric material.

11. A method of forming a fin field effect transistor (finFET) comprising:
fabricating a semiconductor fin formed on a base, the fin further including a body area having substantially the same width between a first vertical surface and a second vertical surface;
depositing a gate dielectric over exposed surfaces of the body area, the gate dielectric having a gate dielectric thickness;
depositing a dielectric over exposed surfaces of the semiconductor fin so that the dielectric has a height greater than a combined height of the body area and the gate dielectric thickness;
etching, in the dielectric, a first contact opening adjacent to the first vertical surface, wherein there is a first dielectric thickness between the first vertical surface and the first contact opening;
etching, in the dielectric, a second contact opening adjacent to the second vertical surface, wherein there is a second dielectric thickness between the second vertical surface and the second contact opening;
filling the first contact opening with a first contact; and
filling the second contact opening with a second contact, wherein the first dielectric thickness and the second dielectric thickness are configured to allow the first and second contacts to modulate the body area of the fin.

12. The method of claim 11, further comprising:
defining a source on a first side of the body area and a drain on a second side of the body area.

13. The method of claim 12, wherein the source, drain, and body area of the fin are defined by an angled dopant implantation, angled with respect to the first and second vertical surfaces and masked by the first and second contacts.

14. The method of claim 13, wherein the angled dopant implantation is on the order of 45 degrees with respect to the first and second vertical surfaces.

15. The method of claim 13, wherein the first and second contacts defining the source, drain, and body area are a respective first spire and a second spire made of a dielectric.

16. The method of claim 11, further comprising:
depositing a top fin dielectric layer on a top fin area of the body area having a dielectric thickness; and
forming a top fin contact on the top fin dielectric layer, wherein the vertical dielectric thickness separating the top fin area and the top fin contact is configured to allow the top fin contact to modulate the body area of the fin.

17. The method of claim 16, wherein the top fin contact is coupled to the first contact and the second contact.

18. The method of claim 16, wherein the top fin contact is electrically insulated from the first contact and the second contact.

19. The method of claim 16, wherein the first contact, the second contact, and the top fin contact are made of a conductive material.

20. The method of claim 16, wherein the first dielectric thickness, the second dielectric thickness and the vertical dielectric thickness are made of one or more layers of different dielectric material.
